(19) United States
(12) Patent Application Publication
(10) Pub. No.: US 2022/0298622 A1
(43) Pub. Date: Sep. 22, 2022

(54) Electron-Beam Deposition of Striated Composite Layers for High-Fluence Laser Coatings

(71) Applicant: University of Rochester, Rochester, NY (US)

(72) Inventor: James B. Oliver, Rochester, NY (US)

(21) Appl. No.: 17/695,476

(22) Filed: Mar. 15, 2022

Related U.S. Application Data
(60) Provisional application No. 63/161,840, filed on Mar. 16, 2021.

(51) Int. Cl. C23C 14/30; C23C 14/08; C23C 14/50

(52) U.S. Cl. CPC C23C 14/30; C23C 14/083; C23C 14/505; G02B 5/281

(57) ABSTRACT

Striated composite layers are deposited using reactive electron-beam evaporation of hafnium dioxide and silicon dioxide sublayers in a planetary rotation or linear translation system in which the hafnia and silica vapor plumes are present at the same time, and yet the hafnia and silica sublayers are distinct. The resulting StriCom materials exhibit significant improvements in laser-induced damage thresholds, thin-film stresses, environmental sensitivity, and control of refractive indices relative to monolayer hafnia films.

### REFERENCE TO RELATED APPLICATION

This patent application claims priority to U.S. Provisional Patent Application Ser. No. 63/161,840 filed Mar. 16, 2021 and incorporates by reference the entire contents thereof.

### GOVERNMENT RIGHTS

This invention was made with government support under DE-FC52-92SF19460 awarded by Department of Energy. The government has certain rights in the invention.

### FIELD

This patent specification pertains to coatings useful primarily in optics to improve optical and other properties of components of optical systems.

### BACKGROUND

This patent specification includes numbers in square brackets that refer to publications fully identified at the end of the written description. Each of the cited publications is hereby incorporated by reference.

Modifications of traditional evaporated and sputtered thin-film optical materials have long been pursued to achieve different film properties including refractive indices, film stresses, and laser damage thresholds. Such modifications have resulted from manipulation of deposition rate/oxygen backfill [1], deposition of material mixtures in an evaporation source [2], co-deposition of 2 or more materials [3,4], and the use of very thin alternating layers to create a composite striated material [5-7]. There are significant issues with the evaporation of material mixtures because it is difficult to maintain a consistent ratio of the constituent materials throughout the deposition process; typically, the difference in evaporation temperatures of the constituent materials can make this nearly impossible. Likewise, the simultaneous use of multiple deposition sources can lead to spatially non-uniform material mixtures since the ratio of the component materials can vary significantly throughout the overlap of the vapor plumes in the deposition chamber.

The use of striated composite (StriCom) layers presents a potential approach to incorporate material mixtures in large-aperture evaporated coatings. This could be in the form of anisotropic mixtures, without the formation of new electronic states, or by the fabrication of sufficiently thin layers to yield a higher electronic bandgap for the composite material than the weakest component material [5,7]. This approach is problematic for evaporated films, since the layers are typically rougher and with less-continuous interfaces than more-energetic deposition approaches such as ion-beam sputtering or atomic-layer deposition. Nevertheless, based on reported results [5,7,8], the potential increase in the composite-material bandgap and corresponding electric-field-based laser-induced-damage threshold could engender interest in the pursuit of such a coating.

Striated composite materials are a combination of different materials with a structure at the molecular level organized in a manner that provides distinct properties (such as optical, mechanical, electrical) that are advantageous relative to the constituent materials. For example, of specific interest for such materials is the refractive index in combination with the laser-induced damage threshold (LIDT) of the material. A StriCom material within the context of this patent application will provide a higher damage threshold for a film with a given refractive index. The distinctive properties of such materials are the result of the way the molecules (ions) of each constituent material connect with the complementary material molecules. This arrangement is such that there is no distinctive film structure (where within each layer the material structure is that of the specific constituent material, such as in columnar materials) but a continuum of interconnected and interacting molecules. In a specific implementation, one may portray the coupling at the molecular level as involving a first material that is deposited in the form of a porous material and a second material that undercoats or fills the pores of the first material while thin layers of the materials are alternately deposited.

A specific subcategory of stratified composite materials are the nanolaminate structures which have been described as having electronic states based on the relative thickness of the quantum well layer (high-refractive-index layer) and the barrier layer (low-refractive-index layer), with the relative thicknesses and resulting performance having been explored [9]. The primary conclusion is that the high-refractive-index material must be sufficiently thin to enable tunneling into the surrounding barrier layer. For example, Willemsen et al found that the effective quantum well thickness for tantala is 0.2 nm; thicknesses greater than this would maintain a constant electronic bandgap, based on the tantala layer, while the effective-medium refractive index would be based on the relative content of high- and low-refractive-index material [9]. A deposition approach enabling sub-nanometer layer thicknesses of both hafnia and silica could maximize both the electronic bandgap and refractive index.

As illustrated in FIG. 1a, traditional optical interference coatings for the near-infrared spectral region consist of a series of alternating layers with physical thicknesses of the order of 100 nm. Very thin sub-layers are used to form an overall composite layer with each individual contribution having a thickness of the order of 1 nm. A primary difficulty in depositing such layers by electron-beam evaporation is stopping and starting the deposition source(s), particularly while maintaining a controlled deposition rate and spatially uniform coating. To make the incorporation of such an approach viable, the substrate must be rotated or translated to achieve a nominally uniform deposition, and the evaporation source must be allowed to stabilize before proceeding with each sub-nanometer deposition. Uniformity can be modeled and the deposition geometry for each material must be appropriately configured but based on past efforts [10-12] it is anticipated that these are significant challenges for system design. Evaporation processes are also problematic for such coatings, given the extremely low energies and corresponding adatom mobility of the condensing film. Steinecke et al note that evaporation cannot be used for the manufacture of quantized nanolaminate structures, given the low deposition energy [7]; if this is true, evaporated StriCom films should exhibit the properties of mixtures, without the increase in the electronic bandgap relative to the high-index constituent of the composite material. To deposit controlled-thickness layers, a substrate passing through a deposition zone, with a fixed-rate vapor flux and a given translation velocity, should be coated with a defined layer thickness based on the time in the evaporant flux and the deposition rate as considered for extreme-ultraviolet (EUV) mirrors [13]. By altering translation speeds, deposition rates, and physical dimensions of the deposition zones, differences in film thickness can be realized, corresponding to differences in the sublayer thicknesses of the materials being deposited.

### SUMMARY

According to some embodiments, a method of coating a substrate with a striated composite (StriCom) material comprises: providing a first stabilized vapor plume of a first deposition material and a concurrently existing second stabilized vapor plume of a second, different deposition material; and exposing a substrate, in vacuum, to the first vapor plume for a selected time interval while shielding the substrate from the second plume and to the second vapor plume for a second, subsequent time interval while shielding the material from the first plume; wherein the first and the second time intervals are selected for depositing two distinct sublayers at least one of which has a thickness less than the thickness of a layer that maintains a selected optical property of the material of the sublayer. The method may further include one or more of the following: the StriCom material can be configured to interact with light and the thickness of at least one of the sublayers can be much less than the wavelength of said light, preferably at least an order of magnitude less than said wavelength; said exposing can comprise rotating the substrate relative to said plumes and shielding the substrate from one of said plumes while exposing the substrate to the other plume and can further comprise rotating the substrate both about an axis passing through the substrate and an axis that is laterally spaced from the substrate; said shielding can comprise providing an upwardly extending shield between laterally spaced sources of the first and the second deposition materials and a laterally extending shield that is above the upwardly extending shield and has respective openings for the first and the second plumes to reach the substrate when the substrate is passing over a respective one of said openings; positioning said openings in the laterally extending shield to match a selected angular extent of the substrate rotation; positioning said openings in the laterally extending shield to match an angular extent of the substrate rotation for each of said plumes; said exposing can comprise causing relative linear translation motion between said substrate and said plumes; the providing step can comprise providing hafnia as one of said plumes and silica as the other, providing refractory oxides as said materials, and/or providing fluoride coating materials as said materials for the plumes; and said exposing can comprise forming said StriCom with sublayers each of which is no more than 5 nanometers or no more than 2 nanometers thick or is sub-nanometer in thickness, on average over a selected area.

According to some embodiments, an electron beam evaporation system for forming Striated Composite (StriCom) coatings comprises: a source of a first stabilized plume of a first deposition material and a concurrent second stabilized vapor plume of a second, different deposition material; a substrate and a carrier supporting the substrate and configured to cause relative motion between the substrate and the plumes; shielding configured to keep said substrate exposed to only one of said plumes during a first portion of said relative motion and only the other of said plumes during a second portion of said relative motion; and a vacuum enclosure containing said plumes, carrier, substrate and shielding; whereby a first sublayer of one of said materials is deposited on the substrate in the course of said first part of the relative motion and a distinct second sublayer of the other material is deposited on the first sublayer in the course of said second portion of the relative motion to thereby form said StriCom coating and at least one of the sublayers has a thickness several times less than a thickness at which the sublayer material retains selected optical properties of the bulk material. The system may further include one or more of the following: said source of plumes can comprise first and second materials laterally spaced apart in said vacuum enclosure, and said shielding can comprise an upwardly extending partition between the two materials; said shielding can further comprise a laterally extending partition that is above said upwardly extending partition and includes a first opening aligned with said first plume and a second opening aligned with said second plume; said carrier can comprise a support positioned above said laterally extending partition and configured to rotate to thereby move the substrate first through one of said openings and then through the other opening; said StriCom coating can comprise sublayers each of which, on average over a selected area, is no more than 5 nm or 1 nm or 0.5 nm of 0.2 nm thick; and one of said plumes can be hafnia and the other silica or at least one of the plumes can be a refractory oxide or a fluoride coating material.

According to some embodiments, an electron beam evaporation system for forming StriCom coatings comprises: a source of a first stabilized plume of a first deposition material and a concurrent second stabilized vapor plume of a second, different deposition material; a substrate and a carrier supporting the substrate and configured for rotary motion relative to said plumes and position above said sources of plumes; and a shielding comprising an upwardly extending partition between said plumes and a laterally extending partition that is over said upwardly extending partition but under said carrier and has first and second openings aligned with the sample during respective portions of the rotary motion of the carrier; whereby a sublayer of one of said materials is deposited on the substrate while the substrate is aligned with one of said openings and a sublayer of the other material is deposited on the sublayer of the first material while the substrate is aligned with the other one of said openings, to thereby form said StriCom coating in which at least one of the sublayers is several times thinner than the wavelength of a selected light. The system can further include one or more of the following: one of said plumes is hafnia and the other is silica; the sublayer materials are refractory oxide coating materials; the sublayer materials are fluoride coating materials; said shielding and the speed of relative motion between the substrate and said plumes are configured to form uniform sublayer thicknesses over substantially the entire area of the substrate, resulting in a spatially uniform StriCom layer in both thickness and refractive index; the shielding is configured to form a StriCom material in which the relative content of the materials of said plumes varies with position on the substrate as a function of radius or linear dimension of the substrate, thereby varying a refractive index of thickness profile of the StriCom material as function of radius of linear coordinates of the substrate.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which principles of the invention are utilized, and the accompanying drawings of which:

FIGS. 1a and 1b illustrate layers of a conventional coating for an interference filter and layers of a striated-composite (StriCom) coating respectively.

FIGS. 2a and 2b show an electron-beam deposition system for StriCom materials in perspective views from two different viewpoints, according to some embodiments;

FIGS. 3a and 3b are TEM images of intentionally thickened stack of layers from which thicknesses of sublayers can be deduced, according to some embodiments;

FIGS. 4a-4c are graphs of percent transmission of light vs. wavelength for different StriCom monolayers under different conditions; and

FIG. 5a is a graph of laser-induced damage threshold vs. composite refractive index of hafnia/silica StriCom monolayers and FIG. 5b is a graph of such damage threshold vs. rotation speed of a sample carrier, according to some embodiments.

### DETAILED DESCRIPTION

A detailed description of examples of preferred embodiments is provided below. While several embodiments are described, the new subject matter described in this patent specification is not limited to any one embodiment or combination of embodiments described herein, but instead encompasses numerous alternatives, modifications, and equivalents. In addition, while numerous specific details are set forth in the following description to provide a thorough understanding, some embodiments can be practiced without some or all of these details. Moreover, for the purpose of clarity, certain technical material that is known in the related art has not been described in detail to avoid unnecessarily obscuring the new subject matter described herein. Individual features of one or several of the specific embodiments described herein can be used in combination with features of other described embodiments or with other features. Further, like reference numbers and designations in the various drawings indicate like elements.

According to some embodiments, a new approach uses electron-beam physical vapor deposition (EBPVD) but differs from known EBPVD by depositing distinct successive sublayers of two distinct different materials in a continuous process in which vapor plumes of the two deposition materials are concurrently present in the same deposition chamber. Concurrent vapor plumes of different materials are known to have been used for depositing layers in which the two materials are mixed but not for depositing distinct sublayers of different materials. To deposit distinct layers, successive deposition chambers have been used, or the same chamber has been reconfigured between deposition of different materials. The new approach described in this patent specification does not require moving the substrate for the film from one deposition chamber to another or having to reconfigure a deposition chamber after depositing one material and before starting the deposition of another material.

According to some embodiments, the new approach uses a deposition chamber in which stabilized vapor plumes of plural, for example two, different deposition materials are concurrently present but the substrate is effectively exposed to only one of the plumes at a time. In a non-limiting example, a StriCom material of distinct sublayers of hafnia and silica is formed on a substrate with desirable properties such as very high resistance to damage by high-power laser beams. For interaction of the StriCom material with light of a selected wavelength, the thickness of a sublayer of a constituent material is less (on the average over a selected area of, for example a square cm) than a thickness of the constituent material that can maintain desired optical properties of that constituent material. For example, the thickness of a sublayer of the StriCom material is several times less, and preferably greater than an order of magnitude less, than the wavelength of light with which the StriCom material is to interact. The preferred materials for at Silica is not a refractory oxide, and it is the preferred material for 1 of the sublayers.

least one and preferably both sublayers are oxides and/or fluorides.

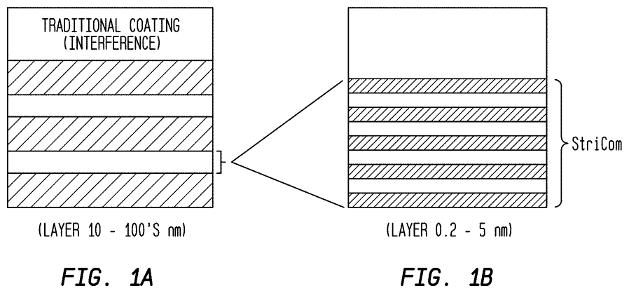

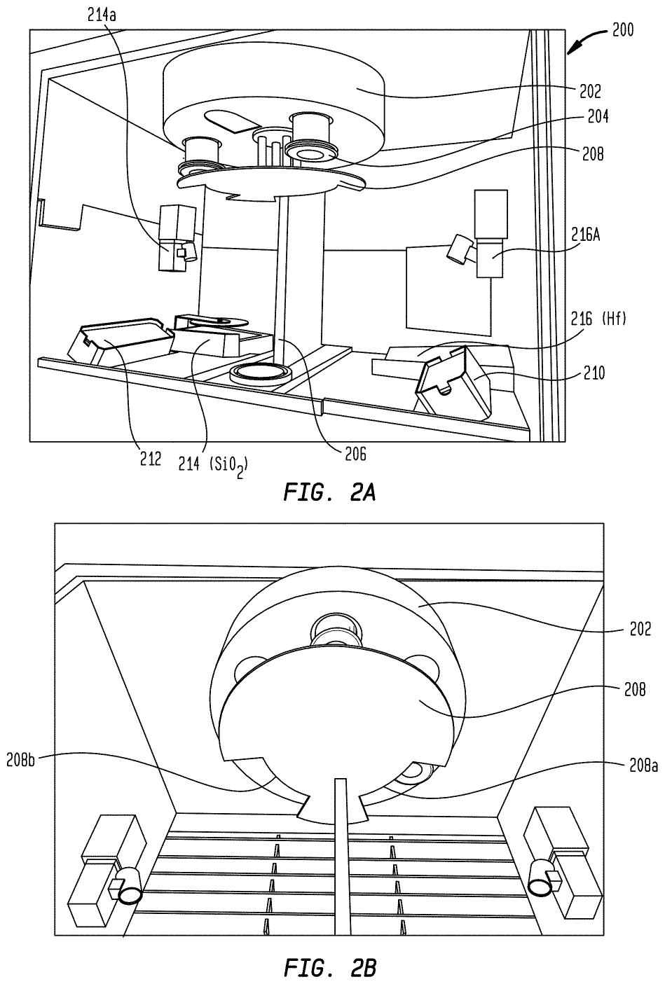

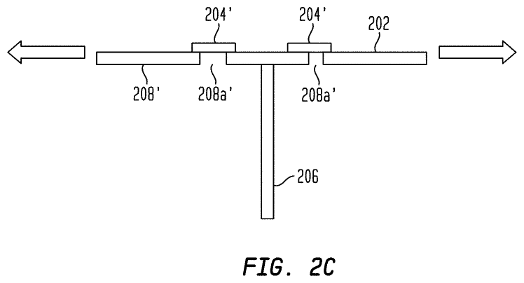

FIG. 1b illustrates a nanolaminate StriCom material and FIGS. 2a and 2b illustrate an example of an evaporation system for forming StriCom layers according to the new approach. A StriCom layer shown in FIG. 1b and made of alternating sublayers of two or more different material can replace some or all of the thicker conventional layers shown in FIG. 1a. Some of the components are like those in a known evaporation system [10] in that the system still uses a 1.37-m coating system 200 with a rotating platform 202 supporting one or more substrates 204 on which the desired film is deposited. In some embodiments, the rotating platform 202 can be implemented as a planetary platform that rotates a substrate both about an axis passing through the substrate and an axis laterally spaced from the substrate, as in U.S. Pat. No. 3,128,205 incorporated by reference herein. The new system further includes an upwardly extending shield 206 to help keep the vapors from the two deposition sources laterally separated and also includes a laterally extending shield 208 that is immediately above shield 206 and further helps keep the two vapor plumes from mixing. The laterally extending shield 208 has two peripheral cutouts, 208a and 208b that are angularly spaced from each other. Electron-beam sources of the two deposition materials, hafnia (at 216) and silica (at 214) in this example, are placed near the walls of the coating chamber and are monitored by respective quartz crystal monitors 216a and 214a. Quartz heaters at 210 and 212 can provide substrate heating as may be desired for the given deposition process.

Shields 206 and 208 block most deposition except deposition from one of the sources at a time when a substrate aligns vertically with one of the openings or cutouts 208a and 208b. The shields in effect form a negative mask for the coating deposition. Placing the electron-beam evaporation sources 216 and 214 near the walls of the coating chamber helps isolate two regions in the chamber, each of which has only one vapor plume present, forming the two deposition zones. An array of 50.8-mm-diameter substrates used in this example rotates past each source in planetary rotation, each substrate being exposed to the vapor flux of the respective deposition material for a controlled angular sector of the overall rotation-system path of 360°. Mask inserts of various angular widths can be used (e.g., 30, 45, 60, and 90°), enabling changes in the relative thickness of each material in the StriCom structure without altering the rotation speed or deposition rate. One or both openings 208a and 208b can be shaped such that different radii of the substrate experience different dwell times in a respective plume, thereby making one or both sublayers vary in thickness with respect to the radius of the substrate when the substrate is rotating about an axis passing through the substrate in addition to rotating relative to the plumes. If the substrate moves linearly relative to the plumes, the thickness can vary along a linear coordinate. For either rotary or linear motion of the substrate relative to the plumes, the opening and the substrate-plumes relative speed can be configured for uniform thickness or other properties of the resulting sublayer(s) or StriCom deposited material.

FIG. 2c illustrates an alternative deposition system that is discussed in paragraph 35 below.

The deposition rate of hafnia remained constant at 0.12 nm/s throughout the deposition in this example, to avoid rate-based changes in the stoichiometry of the deposited film leading to an additional impact on the laser-induced damage threshold. The rotation speed was used to adjust the dwell time of the substrate in the hafnia deposition zone and thus, together with the angular extent of the mask opening, control the layer thickness of each hafnia sublayer. The silica deposition rate was then used to adjust the thickness of its respective sublayers relative to those of the hafnia. In this example, the substrate was heated to 200° C., and the chamber was evacuated to less than 2×10′ Torr before beginning the process. Oxygen was introduced to maintain a chamber pressure of 1×10′ Torr throughout the deposition.

Given the sub-nanometer thicknesses of the layers, direct imaging of the striated layer structure to confirm the resulting dimensions can be difficult. Layers can be made thicker by reducing the planetary rotation speed and thereby depositing individual sublayers of sufficient thickness so thickness can be more easily measured. A coating sample was removed from a coated silicon wafer using a Zeiss-Auriga scanning-electron microscope with focused-ion-beam (SEM/FIB), then imaged in a FEI Tecnai F20 G2 Scanning Transmission Electron Microscope in a bright field mode. Refractive index and film-thickness determinations are modeled based on transmission measurements in a Perkin Elmer Lambda 900 spectrophotometer and ellipsometry using a Woolam VASE variable-angle spectroscopic ellipsometer.

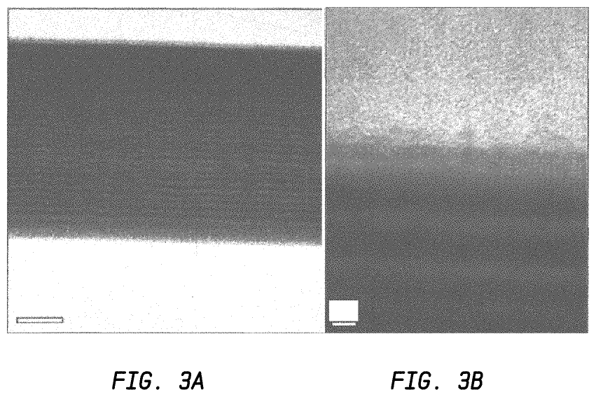

FIGS. 3a and 3b show TEM images of a StriCom section intentionally fabricated with thicker sublayers as described above so the sublayers can be resolved. These thicker sublayers are of the order of 5 nanometers, suggesting that the thinner sublayers fabricated as described further above are, on average over the spatial extent, no more than 5 nm thick and as thin as 0.5 nm or 0.2 nm.

Surface flatness measurements of 1-in.-diam substrates were performed on a Zygo New View white-light interferometer in a controlled-humidity enclosure using both nitrogen-purged and humid air to achieve 0% and 40% relative humidity, respectively. Samples were nitrogen purged for 15 h to stabilize the dry coating stress. Measurements were corrected for cavity irregularity by referencing a λ/50 calibration flat, and all measurements subtracted the pre-coating flatness measurement of the individual substrate. The uncoated surface of the samples was measured to avoid interferometric phase errors from the coating.

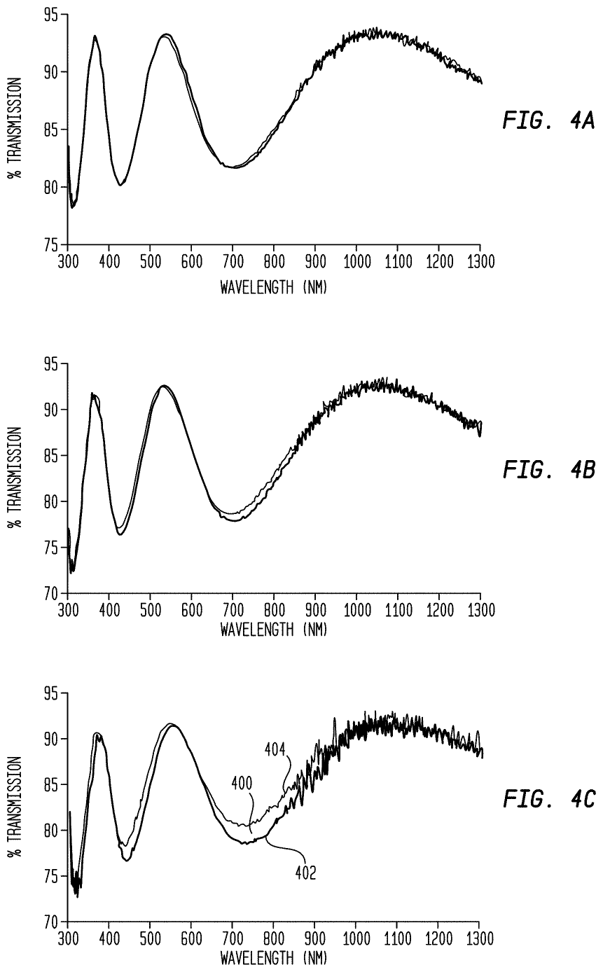

FIGS. 4a-4c show spectral transmission measurements of three StriCom monolayers fabricated using the method described above and can indicate susceptibility to aging and film porosity. The vertical scale is percent transmission of light and the horizontal scale is wavelength of the light in nanometers. FIG. 4a shows the transmission vs wavelength plot for the first sample and three curves that nearly merge (but can be differentiated better in FIG. 4c). FIG. 4b shows plots for a second sample. FIG. 4c shows plots for a third sample. In each of FIGS. 4a-4c, curve 400 shows initial measurements taken in a 40% humidity environment, curve 402 shows measurements taken 7 days later at the same humidity environment, and curve 404 shows measurements taken after 7 days in a nitrogen-purged, 0% relative humidity environment. The highest refractive index material has the highest fraction of hafnia, the lowest % transmission, and also exhibits the lowest spectral shift due to aging or relative humidity, as seen in FIG. 4a. As the composition includes more silica for the measurements shown in FIG. 4b and then 4c, the refractive index decreases and the spectral and aging shifts increase.

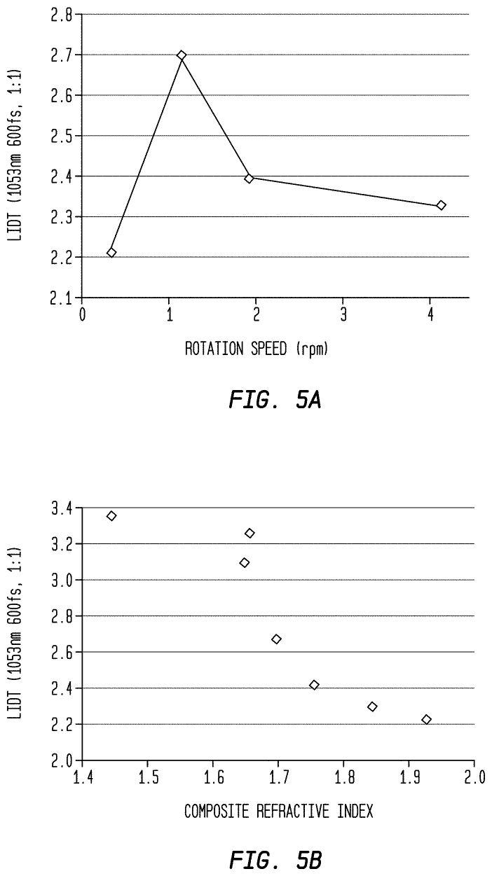

FIGS. 5a and 5b illustrate important properties of StriCom materials fabricated as described above. Laser-damage testing was performed on substrates with StriCom monolayers fabricated as described above, using 600-fs pulses at a wavelength of 1053 nm. The irradiation spot size, illuminated by a 2-m-focal-length mirror, was 350 μm, allowing for the use of fluences up to 50 J/cm². The sample was inspected in-situ under ˜100× magnification using dark-field microscopy, with an observable change in the surface being defined as damage. Post-mortem microscopy was used to confirm the in-situ damage determination. Damage testing may be performed using the 1-on-1 procedure, with an individual site on the substrate illuminated once and then the coating is moved to a pristine site for the next laser pulse, and N-on-1, with the use of a ramped fluence at a fixed position until damage is observed [14].

FIG. 5a shows how laser-induced damage threshold (LIDT) varies with composite refractive index of a particular StriCom structure and FIG. 5b shows how it varies with rotation speed of the sample carrier 202 (FIGS. 2a-2b). The graphs are for hafnia/silica StriCom materials. Hafnia was deposited at 0.12 nm/s with a rotation speed of 4 rpm on cleaved float glass (compared to the film in FIGS. 3a and 3b, which was deposited at the same rate but at a rotation speed of 0.33 rpm; therefore, hafnia sublayers in the StriCom material for FIG. 5a should be 1/12th the thickness of those for FIGS. 3a and 3b). Based on the imaging in FIGS. 3a-3b, and the relative deposition rates, all silica sublayers in the StriCom material for FIG. 5a should also be sub-nanometer. For FIG. 5b, hafnia/silica StriCom monolayers were deposited with a nominal (composite) refractive index of 1.75 as for FIG. 5a but with varying rotation speeds of the substrate carrier 202. A sample from the deposition at a speed of 0.33 rpm is shown in FIG. 3a, with the sublayers becoming thinner in relative proportion to the rotation speed. The point at 4 rpm corresponds to the point in FIG. 5a at n=1.75, though as a different sample in an independent experiment, with agreement on the measured LIDT to 3%.

Table 1 below summarizes experimental results. The sample identifier combines the revolution speed of the substrate carrier 202 (0.33-4.1 rpm) and the deposition rate of the low-refractive-index material, expressed in Angstroms per second (Å/s). As a reminder, the use of a higher speed of revolution results in thinner individual sub-layers, while a higher deposition rate for the low-refractive-index material makes the average refractive index of the composite lower. A broad range of samples was explored, with different material ratios and relative sublayer thicknesses. All coatings were designed to be one half-wave optical thickness at the wavelength of the damage test laser, in order to minimize any change in transmitted intensity within the coating.

| | HfO₂:SiO₂ | HfO₂:SiO₂ | Composite | |
|---|---|---|---|---|
| | Ratio | Ratio | Refractive | LIDT (1053 |
| Sample | (Deposition | (Modeled | Index | nm, 600 fs, |
| Identifier | Rate) | OptiRE) | 1053 nm | 1-on-1) |
| 4.1-L1.0 | 54.5:45.5 | 80:20 | 1.839 | 2.29 |
| 4.1-L2.0 | 37.5:62.5 | 56:44 | 1.736 | 2.41 |
| 4.1-L4.0 | 23.0:77.0 | 31:69 | 1.622 | 3.24 |
| 4.1-L2.0 | 37.5:62.5 | 56:44 | 1.736 | 2.34 |
| 1.9-L2.0 | 37.5:62.5 | 56:44 | 1.736 | 2.40 |
| 1.1-L2.0 | 37.5:62.5 | 56:44 | 1.736 | 2.70 |
| 0.33-L2.0 | 37.5:62.5 | 56:44 | 1.736 | 2.21 |
| 1.1-L4.0 | 23.0:77.0 | 28:72 | 1.608 | 2.25 |
| 1.1-L3.0 | 28.5:71.5 | 36:64 | 1.645 | 2.10 |
| 1.1-L2.5 | 32.5:67.5 | 41:59 | 1.669 | 2.31 |
| 4.1-L4.0 | 23.0:77.0 | 29:71 | 1.613 | 2.35 |
| 4.1-L3.0 | 28.5:71.5 | 39:61 | 1.659 | 2.37 |
| 4.1-L2.5 | 32.5:67.5 | 47:53 | 1.696 | 2.42 |

As noted above, electron-beam evaporation has some key differences from other deposition processes such as ion-beam sputtering or atomic-layer deposition. The deposited film can be a more porous, rougher film with locally discontinuous interfaces, particularly for nanometer-scale layers. Given that many of the StriCom layers are sub-nanometer, this can be of the same order as the possible film roughness. An important question in the use of evaporated StriCom materials is then whether there is a distribution of interfacial errors disrupting the quantum well/barrier layers configuration such that the film behaves as a mixture without the hypothesized improvement in damage threshold relative to the weaker constituent material (hafnia) in ion-beam sputtered nanolaminates. For sufficiently thin layers, the presence of two very differently sized molecules may enable a material structure packing density greater than that typically achieved for an evaporated film, since silica can essentially “fill” the gaps in the hafnia structure, disrupting columnar formation.

The deposition system described above employs a rotary carrier 202 and shielding to form individual deposition zones for each material, such that the substrate is exposed to only one of the hafnia and silica plumes at a time to make the hafnia and silica sublayers in the StriCom material distinct. However, modifications can be envisioned such as linear rather than rotary motion of a substrate carrier relative to plumes of deposition materials and use of deposition materials other than hafnia and silica. For linear rather than rotary motion, the substrate carrier can be replaced with a carrier moving linearly, e.g., left to right in FIGS. 2a and 2b, shield 208 can be replaced with a stationary or moving plate that has one or more openings with which respective moving substrates vertically align for respective time periods as the linearly moving substrate carrier moves relative to the plumes of deposition material vapor.

FIG. 2c schematically illustrates a system that differs from the rotary system of FIGS. 2a and 2b in that a linearly moving substrate carrier 202′ (instead of rotary carrier 202) reciprocates (moving left to right and then right to left) relative to a stationary shield 208′ to thereby expose any one of substrates 204′ to only one of the two concurrent plumes of deposition material at a time through respective opening 208a′ and 208b′ in shield 208′. Each of substrate carriers 202 and 202′ can carry more than one substrate so that a substrate is exposed to the plumes over only a respective portion of a revolution of carrier 202 or the linear motion of carrier 202′. A substrate may be sufficiently large that only a portion lies within the deposition zone at any given time, or different spatial regions on the substrate could lie within different deposition zones simultaneously. A moving substrate carrier can carry multiple samples in a linear or two-dimensional array to match a single opening or multiple openings in a laterally extending shield that can be stationary or moving.

In addition to fabricating a two-material StriCom monolayer, the system and method described above can be used for multilayer coatings containing one or more StriCom layers. For example, a stack of alternating layers of different materials (e.g., hafnia and silica) can be fabricated on the same substrate, containing StriCom layers of more than two different materials, for example by partitioning the vacuum chamber such that three or more plumes of different materials exist concurrently but only one can reach a given substrate at any one time. Different refractory materials can be used as the deposition materials to achieve StriCom materials having different desirable properties according to some embodiments. See examples of refractory materials in [15], incorporated by reference herein. Fluoride coating materials can be used as the deposition materials according to some embodiments; for examples of such materials see [16], incorporated by reference herein. Rotating substrate support 202 can have a planetary motion, as in U.S. Pat. No. 3,128,205, incorporated by reference herein.

The embodiments disclosed herein can be combined in one or more of many ways to provide improved diagnosis and therapy to a patient. The disclosed embodiments can be combined with prior methods and apparatus to provide improved treatment, such as combination with known methods of urological, or gynecological diagnosis, surgery and surgery of other tissues and organs, for example. It is to be understood that any one or more of the structures and steps as described herein can be combined with any one or more additional structures and steps of the methods and apparatus as described herein, the drawings and supporting text provide descriptions in accordance with embodiments.

While preferred embodiments of the present invention have been shown and described herein, it will be apparent to those skilled in the art that such embodiments are provided by way of example only. Numerous variations, changes, and substitutions will now occur to those skilled in the art without departing from the invention. Various alternatives to the embodiments of the invention described herein may be employed in practicing the invention. It is intended that the following claims define the scope of the invention and that methods and structures within the scope of these claims and their equivalents be covered thereby.

The following items are referred to by number in the specification and are contents thereof are incorporated by reference herein:
1. J. B. Oliver, S. Papernov, A. W. Schmid, and J. C. Lambropoulos, “Optimization of laser-damage resistance of evaporated hafnia films at 351 nm,” in Laser-Induced Damage in Optical Materials: 2008 G. J. Exarhos, D. Ristau, M. J. Soileau, and C. J. Stolz eds. (SPIE, Bellingham, W A, 2008), 7132, Paper 71320J.
2. https://www.emdgroup.com/en/brands/pm/patinal.html (March 2020).
3. W. J. Gunning, R. L. Hall, F. J. Woodberry, W. H. Southwell, and N. S. Gluck, “Codeposition of continuous composition rugate filters,” Appl. Opt. 28, 2945-2948 (1989).
4. O. Stenzel, S. Wilbrandt, M. Schürmann, N. Kaiser, H. Ehlers, M. Mende, D. Ristau, S. Bruns, M.1 Vergöhl, M. Stolze, M. Held, H. Niederwald, T. Koch, W. Riggers, P. Burdack, G. Mark, R. Schäfer, S. Mewes, M. Bischoff, M. Arntzen, F. Eisenkrämer, M. Lappschies, S. Jakobs, S. Koch, B. Baumgarten, and A. Tünnermann, “Mixed oxide coatings for optics,” Appl. Opt. 50, C69-C74 (2011)
5. T. Willemsen, P. Geerke, M. Jupe, L. Gallais, and D. Ristau, “Electronic quantization in dielectric nanolaminates,” in Laser-Induced Damage in Optical Materials: 2016 G. J. Exharos, V. E. Gruzdev, J. A. Menapace, D. Ristau, and M. J. Soileau eds. (SPIE, Bellingham, W A, 2016), Proc. SPIE 10014.
6. M. Jupé, M. Lappschies, L. Jensen, K. Starke, D. Ristau, “Improvement in laser irradiation resistance of fs-dielectric optics using silica mixtures,” Proc. SPIE 6403, Laser-Induced Damage in Optical Materials: 2006, 64031A (23 Jan. 2007).
7. M. Steinecke, H. Badorreck, M. Jupé, T. Willemsen, L. Hao, L. Jensen, and D. Ristau, “Quantizing nanolaminates as versatile materials for optical interference coatings,” Appl. Opt. 59, A236-A241 (2020).
8. T. Willemsen, M. Brinkmann, M. Jupé, M. Gyamfi, S. Schlichting, D. Ristau, “Approaches toward optimized laser-induced damage thresholds of dispersive compensating mirrors applying nanolaminates,” Proc. SPIE 10447, Laser-Induced Damage in Optical Materials 2017, 1044712 (22 Mar. 2018).
9. T. Willemsen, M. Jupé, M. Gyamfi, S. Schlichting, and D. Ristau, “Enhancement of the damage resistance of ultra-fast optics by novel design approaches,” Opt. Express 25, 31948-31959 (2017).
10. J. B. Oliver, J. Bromage, C. Smith, D. Sadowski, C. Dorrer, and A. L. Rigatti, “Plasma-ion-assisted coatings for 15 femtosecond laser systems,” Appl. Opt. 53, A221-A228 (2014).
11. J. B. Oliver and D. Talbot, “Optimization of deposition uniformity for large-aperture National Ignition Facility substrates in a planetary rotation system,” Appl. Opt. 45, 3097-3105 (2006).
12. J. B. Oliver, “Analysis of a planetary-rotation system for evaporated optical coatings,” Appl. Opt. 55, 8550-8555 (2016).
13. C. Montcalm, S. Bajt, P. B. Mirkarimi, E. A. Spiller, F. J. Weber, and J. A. Folta, “Multilayer reflective coatings for extreme-ultraviolet lithography,” Proc. SPIE 3331, Emerging Lithographic Technologies II, (1998);
14. A. A. Kozlov, S. Papernov, J. B. Oliver, A. Rigatti, B. Taylor, B. Charles, C. Smith, “Study of the picosecond laser damage in HfO2/SiO20 based thin-film coatings in vacuum,” Proc. SPIE 10014, Laser-Induced Damage in Optical Materials 2016, 100141Y (13 Jan. 2017);
15. J. A. Folta, C. Montcalm, and C. Walton; “METHOD AND SYSTEM FOR PRODUCING SPUTTERED THIN FILMS WITH SUB ANGSTROM THICKNESS UNIFORMITY OR CUSTOM THICKNESS GRADIENTS,” U.S. Pat. No. 6,524,449 B1 (2003).
16. J. F. Shackelford and R. H. Doremus (eds.), Ceramic and Glass Materials: 87 Structure, Properties and Processing. Chapter 6, pages 87-110. Springer 2008.
17. https://www.photonics.com/Articles/Optical_Co._Materials_and_Deposit on/a25493

What is claimed is:

1. A method of coating a substrate with a striated composite (StriCom) material, comprising:
providing a first stabilized vapor plume of a first deposition material and a concurrently existing second stabilized vapor plume of a second, different deposition material; and
exposing a substrate, in vacuum, to the first vapor plume for a selected time interval while shielding the substrate from the second plume and to the second vapor plume for a second, subsequent time interval while shielding the substrate from the first plume;
wherein the first and the second time intervals are selected for depositing two distinct sublayers at least one of which has a thickness less than the thickness of a layer that maintains a selected optical property of the material of the sublayer.

2. The method of claim 1, in which the StriCom material is configured to interact with light and the thickness of at least one of the sublayers is plural times less than the wavelength of said light.

3. The method of claim 2, in which the thickness of at least one of the sublayers is at least an order of magnitude less than said wavelength.

4. The method of claim 1, in which said exposing comprises rotating the substrate relative to said plumes and shielding the substrate from one of said plumes while exposing the substrate to the other plume.

5. The method of claim 4, in which said rotating the substrate comprises rotating the substrate both about an axis passing through the substrate and an axis that is laterally spaced from the substrate.

6. The method of claim 2, in which said shielding comprises providing an upwardly extending shield between laterally spaced sources of the first and the second deposition materials and a laterally extending shield that is above the upwardly extending shield and has respective openings for the first and the second plumes to reach the substrate when the substrate is passing over a respective one of said openings.

7. The method of claim 3, including positioning said openings in the laterally extending shield to match a selected angular extent of the substrate rotation.

8. The method of claim 3, including positioning said openings in the laterally extending shield to match an angular extent of the substrate rotation for each of said plumes.

9. The method of claim 1, in which said exposing comprises causing relative linear translation motion between said substrate and said plumes.

10. The method of claim 1, in which the providing step comprises providing hafnia as one of said plumes and silica as the other.

11. The method of claim 1, in which said providing step comprises providing refractory oxides as said materials.

12. The method of claim 1, in which said providing step comprises providing fluoride coating materials as said materials for the plumes.

13. The method of claim 1, in which said exposing comprises forming said StriCom with sublayers each of which is no more than 5 nanometers thick on average over a selected area.

14. The method of claim 1, in which said exposing comprises forming said StriCom with sublayers at least one of which is, on average over a selected area, sub-nanometer in thickness.

15. The method of claim 1, in which said exposing comprises forming said StriCom with sublayers at least one of which, on average over a selected area, is no thicker than 0.2 nanometers.

16. The method of claim 1, in which the exposing step comprises repeating plural times a sequence of exposing the substrate to the first vapor plume while shielding from the second vapor plume and then to the second vapor plume while shielding from the first vapor plume, to thereby form a StriCom layer that comprises plural alternating sets of said sublayers of the first and second deposition materials.

17. The method of claim 1, further comprising forming on said substrates one or more StriCom layers each comprising said sublayers, wherein each of the sublayers is no more than 5 nanometers thick on average over a selected area, and forming one or more thicker layers of a material thicker that any one of said sublayers and adjacent said one or more of said StriCom layers, to thereby form an interference coating comprising alternating StriCom layers and said thicker layers.

18. An electron beam evaporation system for forming Striated Composite (StriCom) coatings, comprising:
a source of a first stabilized plume of a first deposition material and a concurrent second stabilized vapor plume of a second, different deposition material;
a substrate and a carrier supporting the substrate and configured to cause relative motion between the substrate and the plumes;
shielding configured to keep said substrate exposed to only one of said plumes during a first portion of said relative motion and only the other of said plumes during a second portion of said relative motion;
a vacuum enclosure containing said plumes, carrier, substrate and shielding;
whereby a first sublayer of one of said materials is deposited on the substrate in the course of said first part of the relative motion and a distinct second sublayer of the other material is deposited on the first sublayer in the course of said second portion of the relative motion to thereby form said StriCom coating and at least one of the sublayers has a thickness several times less than a thickness at which the sublayer material retains selected optical properties of the bulk material.

19. The electron beam evaporation system of claim 18, in which said source of plumes comprises first and second materials laterally spaced apart in said vacuum enclosure, and said shielding comprises an upwardly extending partition between the two materials.

20. The electron beam evaporation system of claim 18, in which said shielding further comprises a laterally extending partition that is above said upwardly extending partition and includes a first opening aligned with said first plume and a second opening aligned with said second plume.

21. The electron beam evaporation system of claim 19, in which said carrier comprises a support positioned above said laterally extending partition and configured to rotate to thereby move the substrate first through one of said openings and then through the other opening.

22. The electron beam evaporation system of claim 18, in which said StriCom coating comprises sublayers each of which, on average over a selected area, is no more than 5 nanometers thick.

23. The electron beam evaporation system of claim 18, in which said StriCom coating comprises sublayers at least one of which, on average over a selected area, is no more than a nanometer thick.

24. The electron beam evaporation system of claim 18, in which said StriCom coating comprises sublayers at least one of which, on average over a selected area, is no more than 0.5 nanometers thick.

25. The electron beam evaporation system of claim 18, in which said StriCom coating comprises sublayers at least one of which, on average over a selected area, is no more than 0.2 nanometers thick.

26. The electron beam evaporation system of claim 18, in which one of said plumes is hafnia and the other is silica.

27. The electron beam evaporation system of claim 18, in which at least one of said plumes is a refractory oxide.

28. The electron beam evaporation system of claim 18, in which at least one of said plumes is a fluoride coating material.

29. An electron beam evaporation system for forming StriCom coatings, comprising:
a source of a first stabilized plume of a first deposition material and a concurrent second stabilized vapor plume of a second, different deposition material;
a substrate and a carrier supporting the substrate and configured for rotary motion relative to said plumes and position above said sources of plumes;
a shielding comprising an upwardly extending partition between said plumes and a laterally extending partition that is over said upwardly extending partition but under said carrier and has first and second openings aligned with the sample during respective portions of the rotary motion of the carrier;
whereby a sublayer of one of said materials is deposited on the substrate while the substrate is aligned with one of said openings and a sublayer of the other material is deposited on the sublayer of the first material while the substrate is aligned with the other one of said openings, to thereby form said StriCom coating in which at least one of the sublayers is several times thinner than the wavelength of a selected light.

30. The electron beam evaporation system of claim 29, in which one of said plumes is hafnia and the other is silica.

31. The electron beam evaporation system of claim 29, wherein the sublayer materials are refractory oxide coating materials.

32. The electron beam evaporation system of claim 29, wherein the sublayer materials are fluoride coating materials.

33. The electron beam evaporation system of claim 29, in which said shielding and the speed of relative motion between the substrate and said plumes are configured to form uniform sublayer thicknesses over substantially the entire area of the substrate, resulting in a spatially uniform StriCom layer in both thickness and refractive index.

34. The electron beam evaporation system of claim 29, in which the shielding is configured to form a StriCom material in which the relative content of the materials of said plumes varies with position on the substrate as a function of radius or linear dimension of the substrate, thereby varying a refractive index or thickness profile of the StriCom material as a function of radius or linear coordinates of the substrate.
